(19) United States
(12) Patent Application Publication
(10) Pub. No.: US 2022/0262869 A1
(43) Pub. Date: Aug. 18, 2022

(54) COMMON RGB RESONANCE LAYERS FOR OLED DISPLAYS

(71) Applicant: 3M INNOVATIVE PROPERTIES COMPANY, St. Paul, MN (US)

(72) Inventor: David G. Freier, St. Paul, MN (US)

(21) Appl. No.: 17/626,976

(22) PCT Filed: Aug. 7, 2020
(86) PCT No.: PCT/IB2020/057492

§ 371 Date: Jan. 13, 2022

Related U.S. Application Data
(60) Provisional application No. 62/885,962, filed on Aug. 13, 2019.

(51) Int. Cl. H01L 27/32; H01L 51/52

(52) U.S. Cl. CPC H01L 27/3211; H01L 51/5265; H01L 2251/558; H01L 51/5275; H01L 51/5237; H01L 27/3209

(57) ABSTRACT

A computer-implemented method of designing an organic light emitting diode (OLED) device having a resonance layer. The method includes calculating the reflectance of red, green, and blue spectrums of the OLED device to generate, respectively, red, green, and blue reflectance values. A thickness and possibly a material of the resonance layer is selected such that the red, green, and blue reflectance values are substantially equal to one another or within a particular deviation of one another. The OLED device can have multiple resonance layers, in which case the thicknesses and materials of the resonance layers are selected to provide substantially equal red, green, and blue reflectances.

### BACKGROUND

Resonance layers are extremely useful elements in organic light emitting diode (OLED) emission stacks. They are critical in enabling the high performance of these displays.

### SUMMARY

A need exists for a design criterion for resonance layers that ensures low color shifts and high white point efficiency.

A computer-implemented method of designing an OLED device having a resonance layer includes calculating the reflectance of red, green, and blue spectrums of the OLED device to generate, respectively, red, green, and blue reflectance values. The method also includes selecting a thickness of the resonance layer such that the red, green, and blue reflectance values are substantially equal to one another or within a particular deviation of one another.

An OLED device, designed according to the method, includes components arranged in the following order: a substrate; a first electrode; an emissive layer; a second electrode; a resonance layer; and an encapsulant layer. The resonance layer has a thickness such that red, green, and blue reflectances of the OLED device are substantially equal to one another or within a particular deviation of one another.

### BRIEF DESCRIPTION OF THE DRAWINGS

The accompanying drawings are incorporated in and constitute a part of this specification and, together with the description, explain the advantages and principles of the invention. In the drawings,

FIG. 1 is a diagram of an OLED construction including resonance layers;

FIG. 2 is a diagram of an example device architecture, resonance layers, and characteristic wavelengths;

FIG. 3 shows calculated reflectances at 625 nm (red);

FIGS. 4A and 4B show, respectively, calculated reflectances at 515 nm (green) and 455 nm (blue);

FIG. 5 shows calculated RMS deviation in RGB reflectance;

FIGS. 6A and 6B show calculated approximate device emissivities and dopant emission spectra plotted on a logarithmic wavelength axis;

FIG. 7 shows geometric construction for color mixing analysis;

FIG. 8 shows calculated HTL-optimized RMS deviations from uniform balance;

FIGS. 9A, 9B, and 9C show optimized cavity optical thicknesses;

FIG. 10 shows average primary shift;

FIGS. 11A, 11B, and 11C are diagrams of rigorous emission stack design space; and

FIG. 12 is a diagram of a computing device for calculating the specification of the optical function of the resonance layers for an OLED device.

### DETAILED DESCRIPTION

Embodiments include a specification for red, green, and blue strong cavity OLED devices in an RGB (red-green-blue) display, differing only in the emissive and hole-transport layer components of their cavities, whose common resonance layers diminish differences in the normal-incidence reflectance from within the cavity of the transflective-electrode/resonance-layers/TFE (thin-film encapsulent)-inorganic structure at red, green, and blue wavelengths.

Resonance layers selected according to this specification result in displays exhibiting exceptionally low off-axis color shift and usually also exceptionally high white point efficiency.

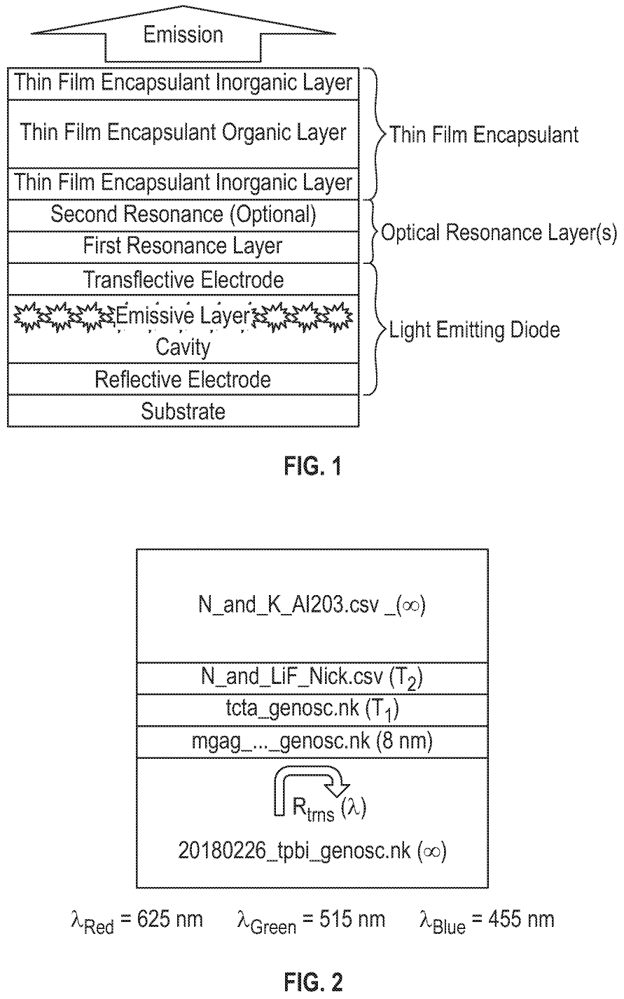

A subject OLED construction, including one or more common resonance layers in the indicated positions, is shown in FIG. 1. The specification of the optical function of the resonance layers involves the criterion that they diminish differences in the subject reflectances at red, green, and blue wavelengths.

Evaluation of the Subject Reflectance (Rₜᵣₙₛ(λ)), where trns is the Effective Reflectivity of Transflective Electrode

The subject reflectance can be evaluated using standard algorithms for the reflection of plane waves by a coherent multilayer structure embedded between two semi-infinite media. The steps in this process are:
1. Identify a device architecture of interest, including the thickness and wavelength-dependent complex index of refraction of the transflective electrode, and the complex indices of refraction immediately below the transfiective electrode and immediately above the top-most resonance layer;
2. Select candidate materials for each resonance layer, characterized by their complex indices of refraction;
3. Select characteristic red, green, and blue wavelengths approximately equal to the wavelength of maximum emission of the red, green, and blue dopants; and
4. Select ranges of candidate resonance-layer thicknesses, and exercise the algorithm to determine the red, green, and blue reflectance for each combination of candidate thicknesses.

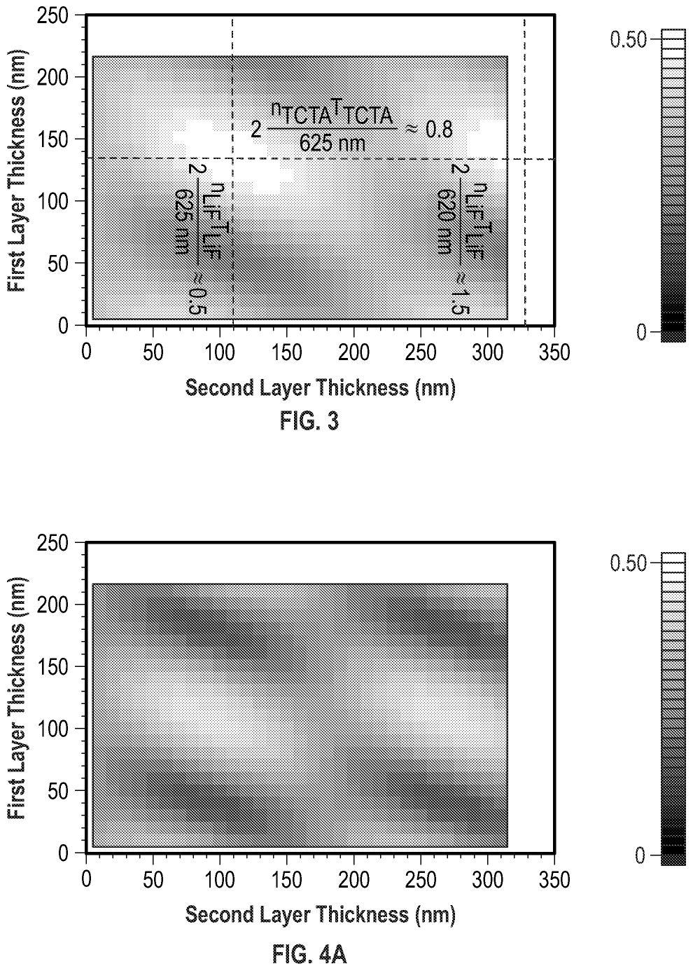

This process is illustrated for the example device architecture, resonance layers, and characteristic wavelengths depicted in FIG. 2.

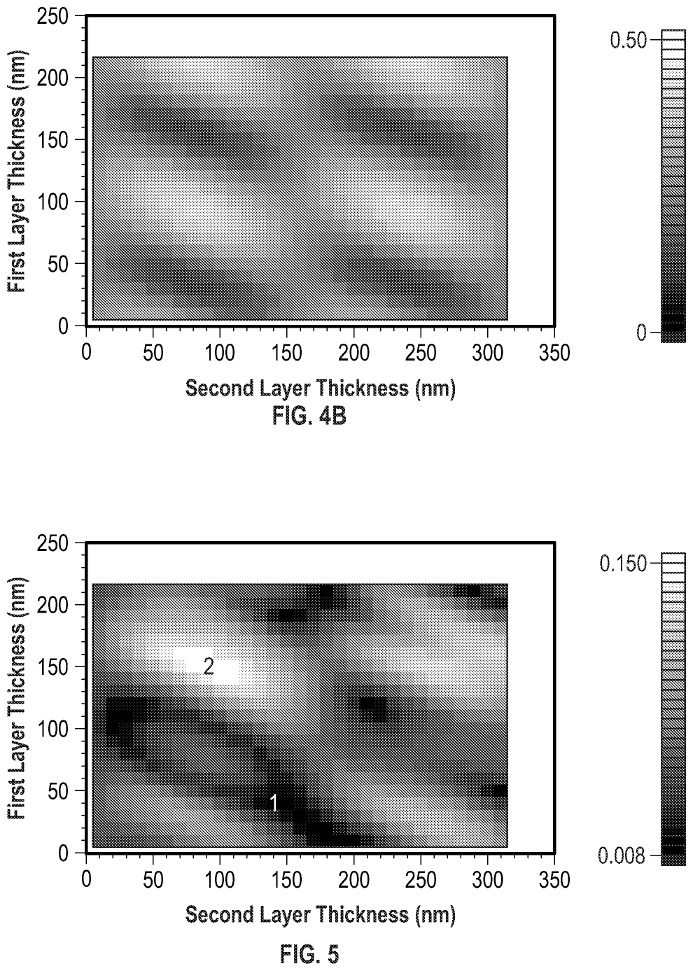

The calculated red reflectance for the example system is depicted in FIG. 3 as a function of the thickness of the first and second resonance layers.

The maximum reflectance occurs when:
1. A wave in the first resonance layer, reflected at the interface with the second resonance layer and then again at the top surface of the transflective electrode, arrives again at the interface with the second resonance layer with a 180-degree phase shift. The reflection from the transflective electrode induces a 108-degree retardation, so that the two-way propagation must induce a 288-degree advance. This occurs when

$$2 \frac{{n}_{TCTA} {T}_{TCTA}}{625 nm} = \frac{\text{?}}{360} = 0.8 ; \\ \text{?} \text{indicates text missing or illegible when filed}$$

2. And simultaneously, a wave in the second resonance layer, reflected at the interface with the TFE-inorganic and then again at the top surface of the first resonance layer, arrives again at the interface with the TFE-inorganic with a 180-degree (or 540-degree) phase shift. There is no net phase shift upon reflection, so that this requires a 180-degree (or 540-degree) advance. This occurs when
3.

$$2 \frac{n \text{?} T \text{?}}{625 nm} = \frac{180}{360} = 0.5 ( or 1.5 ) ; \\ \text{?} \text{indicates text missing or illegible when filed}$$

and
4. In combination, these conditions ensure that a wave in the second resonance layer, reflected at the interface with the TFE-inorganic and then again at the top surface of the transflective electrode, arrives again at the interface with the TFE-inorganic 180-degrees out of phase with the incident wave.

These physical origins of the observed reflectance are described for edification. They need not be known or used to perform the required evaluations of red, green, and blue reflectance.

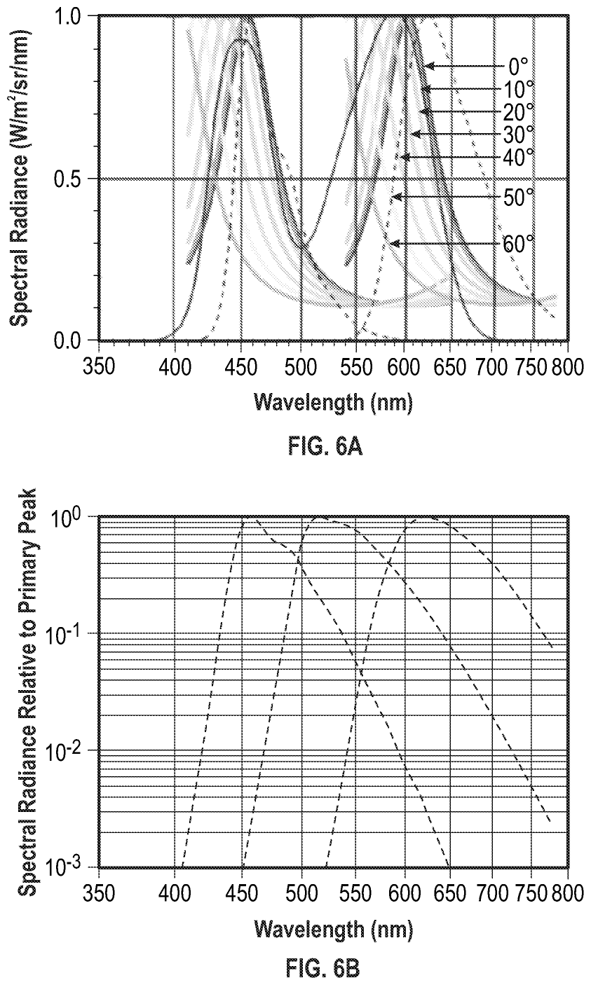

The calculated green and blue reflectance are depicted in FIGS. 4A and 4B.

While the general periodic pattern of high and low reflectance is similar to that of the red reflectance, it is compressed nearly equally in both the first and second resonance layer thickness dimensions. This is not primarily due to dielectric dispersion—the indices of all of the materials in the evaluations (except the transflective electrode) are not substantially different at red, green, and blue wavelengths. It is primarily due to the decrease in the free-space wavelength. The positions of the maxima along both the first and second resonance-layer thickness axes are diminished by the ratio

$$\frac{515}{\text{?}} or \frac{455}{625} . \\ \text{?} \text{indicates text missing or illegible when filed}$$

The transflective electrode in the present example exhibits significant dielectric dispersion between the red, green, and blue wavelengths. In the absence of resonance layers, the reflectance of this electrode is larger in the red than the green than the blue. While modulation due to the resonance layers occurs at all three wavelengths, it occurs about a lower mean value with decreasing wavelength.

The dielectric dispersion of the transflective electrode prohibits attaining equal red, green, and blue reflectance in the absence of resonance layers. The variations in reflectance induced by resonance layers, along with the compression of these with decreasing wavelength, recover the possibility of equal red, green, and blue reflectance.

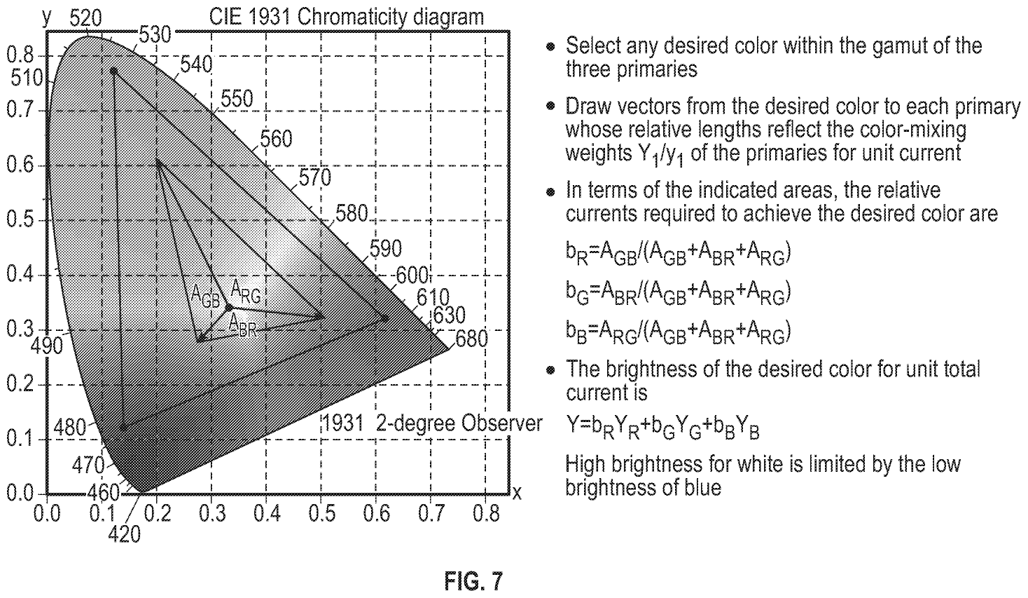

FIG. 5 depicts the rms (root-mean-square) deviations in the red, green, and blue reflectances shown above.

Two example combinations of resonance layer thicknesses are selected to illustrate the impact of equal vs dramatically unequal Rₜᵣₙₛ on performance. The average RGB reflectance is 0.24 at the combination labelled 1, and 0.29 at that labelled 2.

Approximate Device Emission from Rₜᵣₙₛ(λ)

The spectral emission of a device into air is the product of the dopant emission spectrum and the device emissivity. A simple Fabry-Perot model can be used to approximate the wavelength dependence of the device emissivity:

$$Emission ( λ ) ∝ P ( λ ) \times \frac{1}{1 + F {sin}^{2} ( 2 π \frac{{n}_{cav} {T}_{cav} cos {θ}_{cav}}{λ} )} \\ {θ}_{cav} = sin - 1 ( \frac{sin {θ}_{air}}{{n}_{cav}} ) \\ F ≡ \frac{4 R}{{( 1 - R )}^{3}} \\ R = \sqrt{{R}_{reft} {R}_{trns}} \approx \sqrt{{R}_{trns}}$$

Let λₑ denote the wavelength of peak emissivity for some θₐₜᵣ, δλ the full width at half max of the corresponding emissivity, and Δλ₀ the shift of the peak wavelength corresponding to a change in angle Δθₐₜᵣ:

$${λ}_{0} = {n}_{cav} {T}_{cav} cos {θ}_{cav} \\ δ λ = {λ}_{0} \frac{{sin}^{- 1} ( 1 / \sqrt{F} )}{2 π} \\ \frac{{Δλ}_{0}}{{Δθ}_{air}} = {λ}_{0} \frac{Δ ( ln cos {θ}_{cav} )}{{Δθ}_{air}}$$

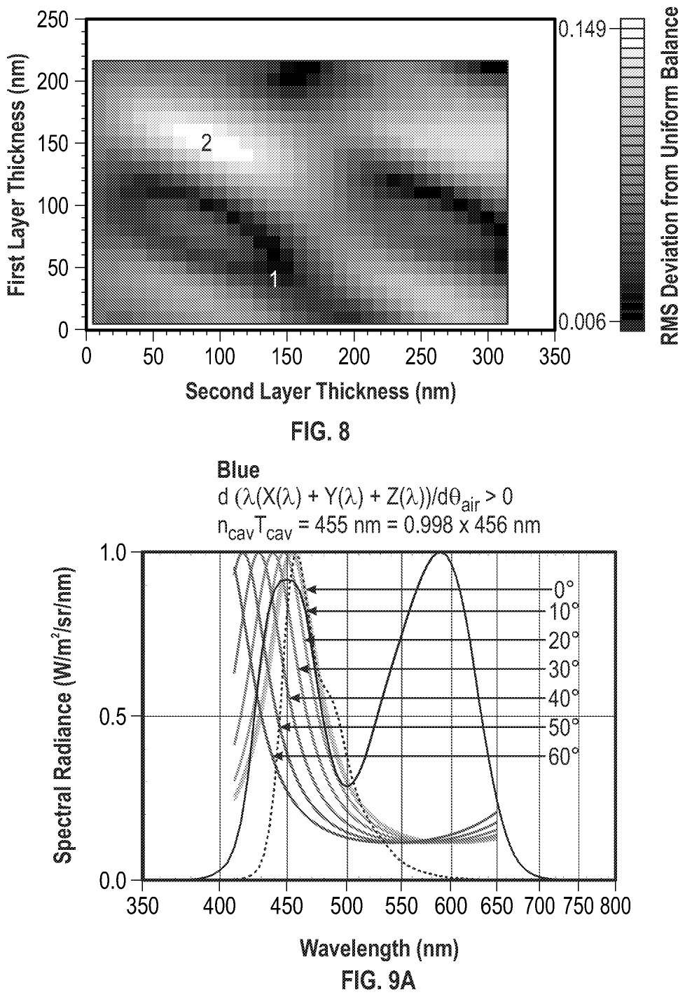

Both the width and the rate of migration of the peak emissivity with increasing θₐₜᵣ are directly proportional to λ₀ and otherwise dependent upon only Rₜᵣₙₛ or n_{cav}. When the red, green, and blue values of Rₜᵣₙₛ and n_{cav} are the same, the approximate red, green, and blue device emissivities corresponding to a common fan of θₐₜᵣ are displaced replicas of one another when plotted on a logarithmic wavelength axis. This is illustrated in FIG. 6A for example red and blue devices with resonance layer thicknesses corresponding to Design Point 1 in FIG. 5.

Red, green, and blue dopant emission spectra often also exhibit a linear stretch with increasing wavelength that is suppressed by a logarithmic wavelength axis. FIG. 6B depicts example spectra for fluorescent blue and phosphorescent green and red dopants. They are approximate displaced replicas.

This means that when the red, green, and blue values of Rₜᵣₙₛ are equal, the red, green, and blue device emission spectra will be approximate displaced replicas of one other when plotted on a logarithmic wavelength axis.

Non-spectral performance characteristics such as brightness and color are evaluated using integrals over wavelength of the device emission spectrum times an appropriate weighting function W(λ). The value of these can be visualized using spectra plotted on a logarithmic wavelength axis by weighting by λW(λ) as opposed to W(λ) and integrating as

∫dλW(λ) Device Emission(λ)=∫d ln λ(λW(λ)) Device Emission(ln λ)

### Off-Axis Color Balance

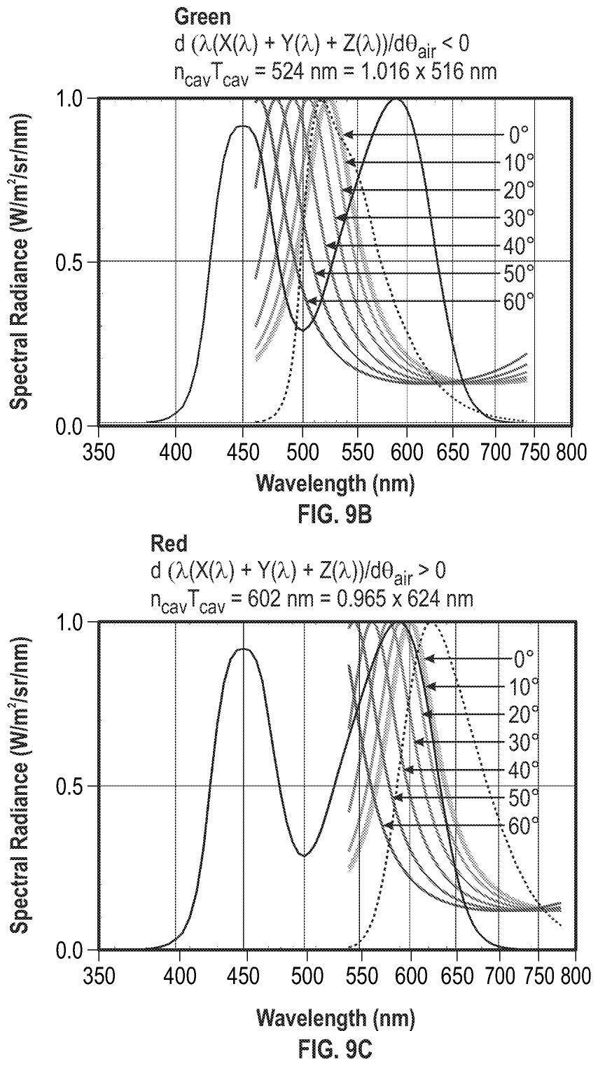

FIG. 7 summarizes a geometric construction which quantifies color-mixing analysis. The relative values of the quantity Yₜ/yₜ for each of the red, green, and blue primaries are central to the analysis. These are called the red, green, and blue color-mixing weights.

The partitioning of unit total current between the red, green, and blue pixels is determined by the on-axis values of 1) the desired mixed color, 2) the primary colors, and 3) the color-mixing weights of the primaries. The current cannot change with changing view off axis. It is therefore critical to maintain both the same primary colors and the same relative values of the color mixing weights off axis as on.

The requirement for constant relative values of the mixing weights off axis is called color balance. The degree of balance is measured by plotting (Yₜ(θ)/yₜ (θ))/(Yₜ(0)/yₜ (0)) as a function of θ for each of the red, green, and blue primaries, and then evaluating the rms deviation between these curves over a range of angles extending to the largest off-axis angle at which low color shift is desired. Normally considered are angles 0→45° with this metric called the rms deviation from uniform balance.

### Hole Transport Layer (HTL)-Optimized Color Balance

The usual remaining degrees of freedom in RGB emission stack design, other than the thicknesses of the two resonance layers, are the optical thicknesses of the red, green, and blue cavities. These are usually adjusted by adjusting the thickness of the hole transport layer component.

For the sake of axial efficiency, the range of optical thicknesses considered should include and not extend too far from the wavelength of peak dopant emission. These wavelengths are 624 nm, 516 nm, and 456 nm for the example red, green, and blue dopants described above.

The color mixing weight Y/y (Y—brightness (cd/m²); y—chromaticity coordinate) is evaluated by integrating the device emission weighted by the sum of the tristimulus response functions W(λ)=X(λ)+Y(λ)+Z(λ). If the red, green, and blue device emission spectra were exact displaced replicas on a logarithmic wavelength axis, and if λ(X(λ)+Y(λ)+Z(λ)) were independent of wavelength, then the red, green, and blue color mixing weight decays would be identical for any red, green, and blue cavity optical thicknesses equal to a common multiple of 624, 516, and 456 nm. However, λ(X(λ)+Y(λ)+Z(λ)) is not independent of wavelength.

Therefore, the role of the optical thickness optimization is to compensate for the local variations in λ(X(λ)+Y(λ)+Z(λ)) near 624, 516, and 456 nm. Chosen to be considered are the ranges 594-634 nm for red, 506-546 nm for green, and 435-475 nm for blue.

The optimization is performed by evaluating the rms deviation from uniform balance for all possible combinations of red, green, and blue optical thicknesses chosen from the selected ranges resolved in 2-nm increments and choosing the combination with the minimum rms deviation. This is repeated for each of the 651 combinations of resonance layer thicknesses in the mapping. Approximately 6 million evaluations are needed. These can be accomplished in seconds to minutes of processing time (depending upon hardware) due to the analyticity of the Fabry-Perot approximation.

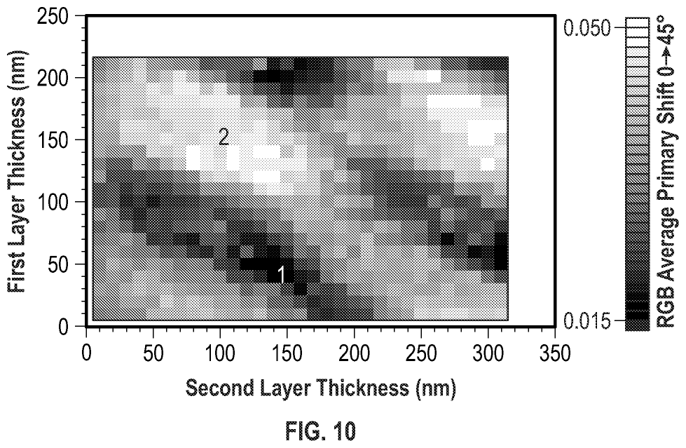

The minimum rms deviation values are depicted in the FIG. 8. There exists a strong positive correlation between the HLT-optimized rms deviation from uniform balance and the rms deviation in RGB reflectance shown previously. In other words, equal RGB reflectance promotes good color balance.

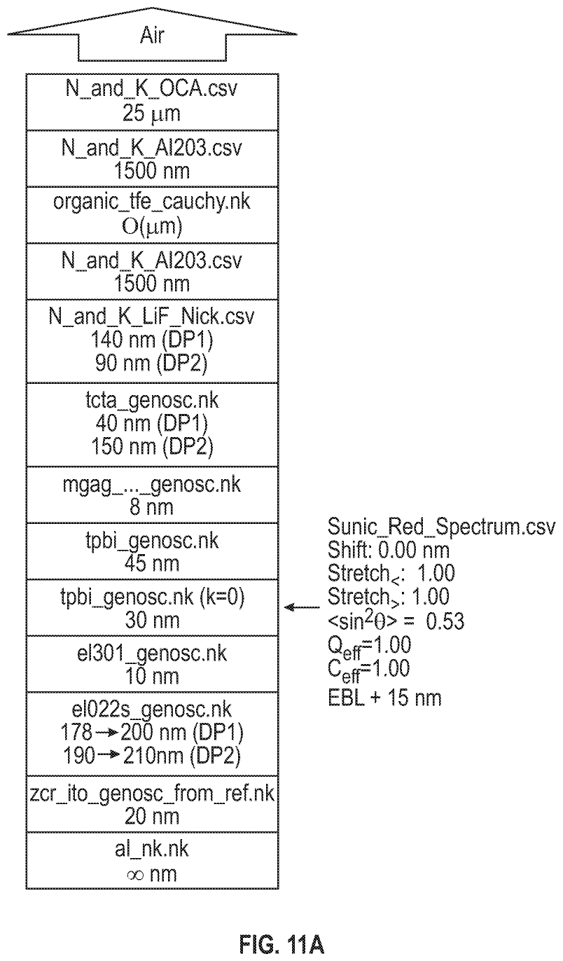

FIGS. 9A-9C depicts the blue, green, and red optimized cavity optical thicknesses and the corresponding device emissivities and dopant emission spectra for the near-equal reflectance and good color-balance at Design Point 1. The function λ(X(λ)+Y(λ)+Z(λ)) is depicted in each plot by the solid black curve.

The blue and red emission occur in regions of wavelength space where λ(X(λ)+Y(λ)+Z(λ)) is increasing with increasing θₐₜᵣ. Green emission occurs where λ(X(λ))+Y(λ)+Z(λ)) is decreasing. Ideally the color mixing weight decays would be identical if λ(X(λ)+Y(λ)+Z(λ)) were constant. Locally positive d(λ(X(λ)+Y(λ)+Z(λ)))/dθₐₜᵣ slows the mixing weight decay; locally negative values accelerate it. A slower decay is accelerated by increasingly crowding the short wavelength edge of the dopant emission spectrum with the device emissivity by thinning the cavity. (This hastens the eventual migration of the centroid of the device emission toward longer wavelengths with increasing θₐₜᵣ.) A faster decay is retarded by further removing the emissivity from the short wavelength edge by thickening the cavity. (This delays the migration.) That is exactly what the optimized cavity optical thicknesses do.

These physical origins of the observed optimal cavity optical thicknesses are described for edification. They need not be known or used to perform the required evaluations of optimal thicknesses which demonstrate the correlation between color balance and low rms deviation in RGB reflectance.

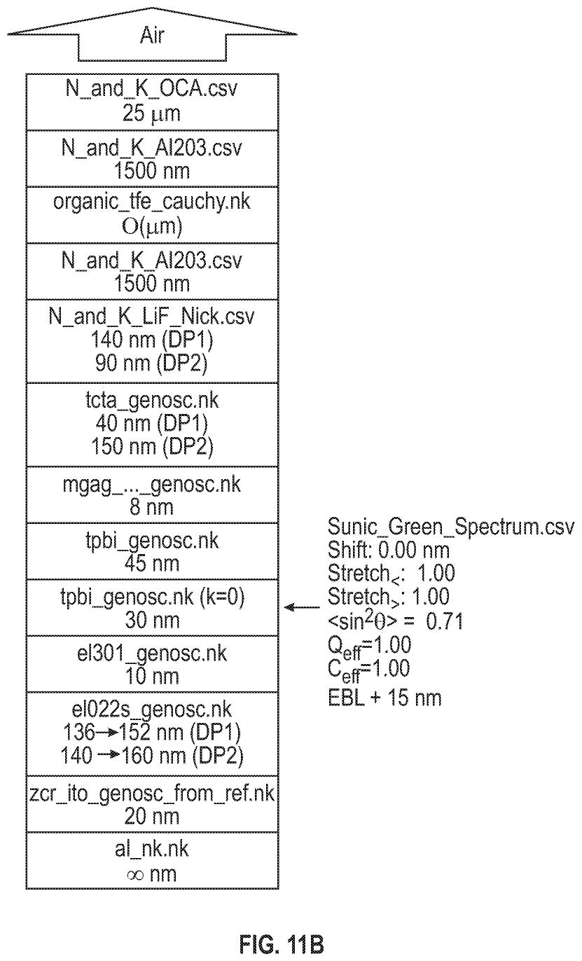

FIG. 10 depicts the average value of the maximum red, green, and blue primary shifts between 0 and 45 degrees for the optimized cavity optical thicknesses as a function of the thicknesses of the two resonance layers. Once again, there exists a strong positive correlation between this average primary shift and the rms deviation in RGB reflectance shown previously. Meaning that equal RGB reflectance promotes both good color balance and low primary shifts.

### Summary of Performance—Design Points 1 and 2

Columns 2 through 5 in Table 1 summarize the performance at Design Point 1. Columns 6 through 9 show these same metrics at Design Point 2. In each case, Rₜᵣₙₛ is the reflectance of the transflective-electrode/resonance-layers/TFE-inorganic structure at 455 nm (blue), 515 nm (green), or 625 nm (red); the values n_{cav}T_{cav} are the optical thicknesses of the cavities optimized for uniform color balance; the values of Δu′v′_{0→45°} are the maximum off-axis color shifts between 0 and 45 degrees; and the values of n_{cav}T_{cav}/λ_{dopant} are the optimized optical thicknesses relative to the peak wavelength of the dopant emission spectrum.

The red and green primary shifts and the rms deviation from uniform balance are much smaller for Design Point 1 than Design Point 2. The blue primary shift is comparable. Therefore anticipated are smaller (and for most colors much smaller) off-axis mixed color shifts for Design Point 1.

The most useful and broadly-accepted measure of device efficiency is the ratio of the brightness emitted on axis to the current density driving the device. This is called the axial efficiency and is usually quoted in Cd/A. No attempt has been made to estimate a known Rₜᵣₙₛ and θₐₜᵣ-dependent scaling of the device emissivity which is critical to the value of the axial efficiency in this Fabry-Perot model. Therefore, no axial efficiencies are quoted in the table.

Three factors exert a strong influence upon the axial efficiency of primaries:
1. Rₜᵣₙₛ. The scaling of the device emissivity generally increases with increasing Rₜᵣₙₛ;
2. The alignment of the peak of the device emissivity for θₐₜᵣ=0 with the peak of the dopant emission. The power emitted on axis generally increases with closer alignment; and
3. The alignment of the peak of the device emissivity for θₐₜᵣ=0 with the peak of the photopic response (Y(λ)) at 555 nm. The on-axis brightness generally increases with closer alignment.

According to these considerations, the following might be expected:
1. A higher blue axial efficiency for Design Point 1 than Design Point 2. All three factors favor Design Point 1;
2. A lower green axial efficiency for Design Point 1 than Design Point 2. The first and third factors favor Design Point 2; and
3. A lower red axial efficiency for Design Point 1 than Design Point 2. The first and second factors favor Design Point 2.

One factor tends to dominate the axial efficiency of mixed colors—the separation in (x,y) color space from the blue primary. When emitting white, the blue pixels, by virtue of their low axial efficiency, often consume half of the total current. (his fraction increases further as the separation from blue decreases.) Therefore, the axial efficiency of white is strongly dependent upon the axial efficiency of blue. Therefore expected is a higher white axial efficiency for Design Point 1 than Design Point 2.

TABLE 1
Summary of Performance.

| | Design Point 1 | | | | Design Point 2 | | | |
|---|---|---|---|---|---|---|---|---|
| | | | Δu′v′ | | | | Δu′v′ | |
| Color | Rₜᵣₙₛ | n_{cav}T_{cav} | 0→45° | n_{cav}T_{cav}/λ_{dopant} | Rₜᵣₙₛ | n_{cav}T_{cav} | 0→45° | n_{cav}T_{cav}/λ_{dopant} |
| Blue | 0.245 | 455 nm | 0.014 | 0.998 | 0.114 | 453 nm | 0.010 | 0.993 |
| Green | 0.233 | 524 nm | 0.013 | 1.016 | 0.301 | 546 nm | 0.047 | 1.058 |
| Red | 0.238 | 602 nm | 0.058 | 0.965 | 0.481 | 622 nm | 0.150 | 0.997 |

| | | |
|---|---|---|
| White | RMS Deviation from Uniform Balance = 0.025 | RMS Deviation from Uniform Balance = 0.149 |

### Rigorous RGB Emission Stack Design

In practice, RGB emission stack design is usually accomplished using complex and essentially exact models subjected to computationally intense design optimization validated by experiment. These models account for numerous effects neglected by a Fabry-Perot approach. These include non-uniform index and absorption within the cavity, dependence upon the position of emission within this non-uniform space, effects of dipole orientation, the impacts of Purcell effects upon radiative decay rates, and the impacts of transmission through components of the stack above the inner TFE inorganic layer. Consider whether the benefits of substantially equal red, green, and blue Rₜᵣₙₛ persist in the outputs of this rigorous design approach.

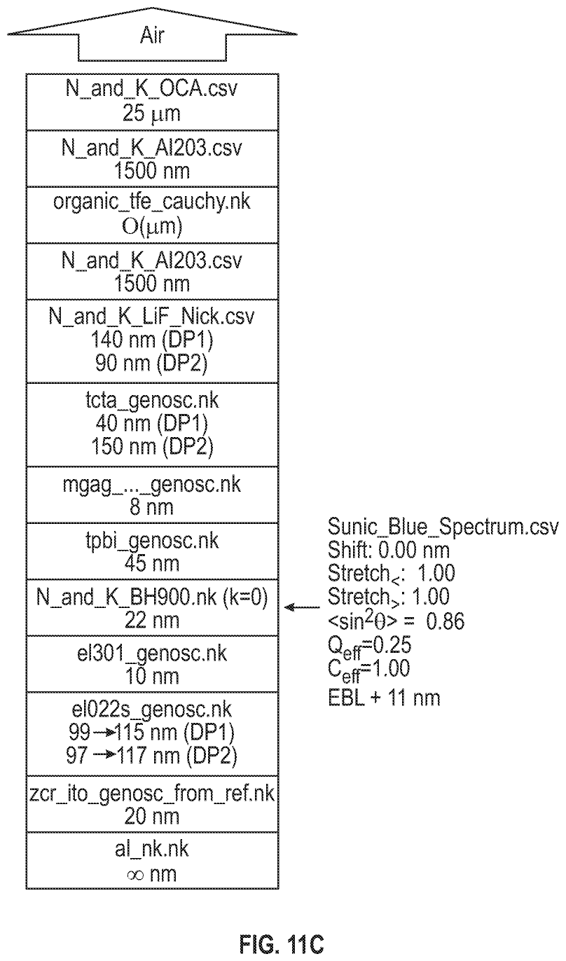

FIGS. 11A-11C depict, respectively, detailed red, green, and blue emission stacks which conform to the specifications of the two design points in the previous analysis herein. That is, the resonance layers are TCTA and LiF with thicknesses as indicated in FIG. 4, the cathode is the same, the TFE inorganic is thick Al₂O₃, the electron transport layer is TPBI, and the dopant emission spectra are the same. The cavity thicknesses are allowed to independently vary by changing the hole transport layer thicknesses within the specified ranges. The indicated ranges result in peak emissivities for θₐₜᵣ=0 near the peaks in the dopant emission spectra at 456, 516, and 624 nm.

The top portion of Table 2 reproduces the Fabry-Perot results for comparison. The bottom summarizes the results of the rigorous design optimization.

For each of Design Points 1 and 2, the red, green, and blue hole transport layer thicknesses were selected to minimize the rms deviation from uniform balance. The resulting optimal values are 180, 136, and 105 nm for Design Point 1, and 188, 136, and 95 nm for Design Point 2. Then the off-axis color shifts and axial efficiencies were evaluated for these optimal thicknesses.

The columns labelled λ₀ (θₐₜᵣ=0) indicate the peak wavelength of the axial emissivity. These values represent the same quantity as the values of n_{cav}T_{cav} in the Fabry-Perot model. The ratios λ₀/λ_{dopant} are included parenthetically. The trends with changing color and design point are very similar to the Fabry-Perot results.

The relative and absolute values of the Fabry-Perot and rigorous primary shifts are similar for Design Points 1 and 2, as are the relative and absolute values of the rms deviation from uniform balance. And as anticipated, the white point shift for Design Point 1 is much smaller than that for Design Point 2.

The relative values of the red, green, blue, and white axial efficiencies for Design Points 1 and 2 are also as anticipated by the Fabry-Perot analysis.

So, the benefits of substantially equal red, green, and blue Rₜᵣₙₛ do persist in the outputs of the rigorous approach.

It should be noted that while zero rms deviation from uniform balance and zero average primary shift ensure zero shift for any color, optimizing the hole transport layer thicknesses to achieve a minimum residual rms deviation and a corresponding small but finite average primary shift does not ensure the most desirable combination of small but finite primary and white point shifts and white axial efficiency. The rigorous design optimization offers several alternatives that might be preferred depending upon priorities. The point of the present invention is that all of these for Design Point 1 are vastly preferred to all of those for Design Point 2. In other words, the minimization of the differences in the red, green, and blue values of Rₜᵣₙₛ identifies a small region within an immense design space of vastly superior overall performance.

TABLE 2
Summary Comparison of Fabry Perot and Rigorous Designs and Performance.

| | Design Point 1 | | | | Design Point 2 | | | |
|---|---|---|---|---|---|---|---|---|
| | | | Δu′v′ | | | | Δu′v′ | |
| Color | Rₜᵣₙₛ | n_{cav}T_{cav} | 0→45° | n_{cav}T_{cav}/λ_{dopant} | Rₜᵣₙₛ | n_{cav}T_{cav} | 0→45° | n_{cav}T_{cav}/λ_{dopant} |
| Blue | 0.245 | 455 nm | 0.014 | 0.998 | 0.114 | 453 nm | 0.010 | 0.993 |
| Green | 0.233 | 524 nm | 0.013 | 1.016 | 0.301 | 546 nm | 0.047 | 1.058 |
| Red | 0.238 | 602 nm | 0.058 | 0.965 | 0.481 | 622 nm | 0.150 | 0.997 |

| White | RMS Deviation from Uniform Balance = 0.025 | | | | RMS Deviation from Uniform Balance = 0.149 | | | |
|---|---|---|---|---|---|---|---|---|
| | Design Point 1 | | | | Design Point 2 | | | |
| | | λ₀ | Δu′v′ | Axial | | λ₀ | Δu′v′ | Axial |
| Color | Rₜᵣₙₛ | (θₐᵢᵣ = 0) | 0→45° | Efficiency | Rₜᵣₙₛ | (θₐᵢᵣ = 0) | 0→45° | Efficiency |
| Blue | 0.245 | 455 nm | 0.017 | 3.4 Cd/A | 0.114 | 434 nm | 0.025 | 1.7 Cd/A |
| | | (0.998) | | | | (0.952) | | |
| Green | 0.233 | 506 nm | 0.009 | 79.8 Cd/A | 0.301 | 522 nm | 0.025 | 80.6 Cd/A |
| | | (0.981) | | | | (1.012) | | |
| Red | 0.238 | 591 nm | 0.040 | 24.1 Cd/A | 0.481 | 607 nm | 0.100 | 25.4 Cd/A |
| | | (0.947) | | | | (0.973) | | |

| | | | | |
|---|---|---|---|---|
| White | 0.007 | 24.4 Cd/A | 0.026 | 19.2 Cd/A |

| | |
|---|---|
| RMS Deviation from Uniform Balance = 0.029 | RMS Deviation from Uniform Balance = 0.087 |

The following are additional considerations for the disclosed method. Materials for the resonance layers can depend upon implementation of the method for a particular OLED device. When two resonance layers are used, the layers can have an index contrast with, for example, one layer having a high index of refraction and the other layer having a low index of refraction. The two resonance layers preferably have a substantial index contrast, or one layer can have a different index than the cathode or TFE. The thicknesses of the resonance layers can also depend upon implementation of the method for a particular OLED device and possibly manufacturing cost or considerations, although thinner layers are generally better. The design methodology can result in multiple good or acceptable points in the plot of thicknesses for two resonance layers as shown, for example, in FIG. 5.

Selecting a thickness, and possibly material(s), of the resonance layer(s) such that the red, green, and blue reflectance values are substantially equal to one another can mean that the reflectance values are within 1% of another, or 5% of one another, or a percentage that is useful.

Selecting a thickness, and possibly material(s), of the resonance layer(s) such that the red, green, and blue reflectance values are within a particular deviation of one another can mean that the reflectance values are within 0.01 of one another, or 0.05 of one another, or a deviation that is useful.

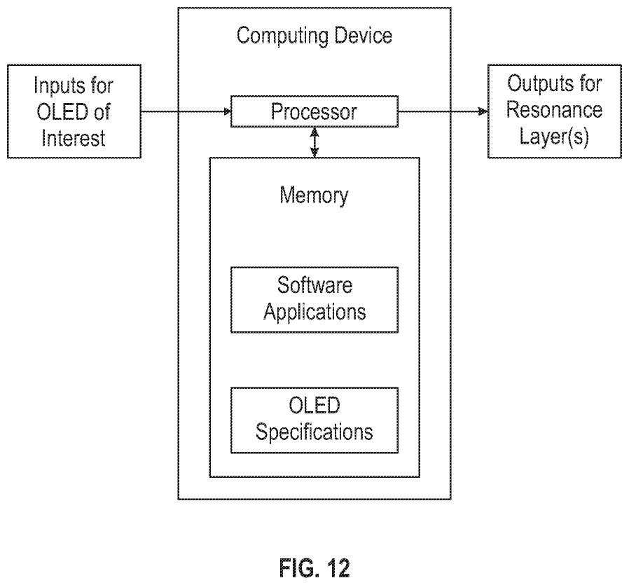

FIG. 12 is a diagram of a computing device for calculating the specification of the optical function of the resonance layers for an OLED device as described herein. The computing device includes a processor and an electronic memory, and possibly other components. The memory can store software applications for execution by the processor in order to process the inputs for an OLED device of interest and generate outputs for the resonance layer(s) of the OLED according to the methods described herein. The outputs can also be stored in the memory as OLED specifications for the OLED of interest. The computing device can be implemented, for example, as a desktop, laptop, or tablet computer.

1. A computer-implemented method of designing an organic light emitting diode (OLED) device having a resonance layer, comprising steps of:
calculating a reflectance of red spectrum of the OLED device to generate a red reflectance value;
calculating a reflectance of green spectrum of the OLED device to generate a green reflectance value;
calculating a reflectance of blue spectrum of the OLED device to generate a blue reflectance value; and
selecting a thickness of the resonance layer such that the red, green, and blue reflectance values are substantially equal to one another or within a particular deviation of one another.

2. The method of claim 1, wherein the selecting step comprises selecting a thickness and a material of the resonance layer such that the red, green, and blue reflectance values are substantially equal to one another or within a particular deviation of one another.

3. The method of claim 2, wherein the selecting step comprises selecting the material based upon an index of refraction of the material.

4. The method of claim 1, wherein the selecting step comprises selecting the thickness resulting in a lowest rms deviation of the red, green, and blue reflectance values.

5. The method of claim 1, wherein the OLED device has another resonance layer, and the selecting step comprises selecting thicknesses of the resonance layer and the another resonance layer such that the red, green, and blue reflectance values are substantially equal to one another or within a particular deviation of one another.

6. The method of claim 1, wherein the OLED device has another resonance layer, and the selecting step comprises selecting thicknesses and materials of the resonance layer and the another resonance layer such that the red, green, and blue reflectance values are substantially equal to one another or within a particular deviation of one another.

7. The method of claim 6, wherein the selecting step comprises selecting the materials based upon indices of refraction of the materials.

8. The method of claim 1, wherein the calculating steps comprise calculating the red, green, and blue reflectances at, respectively, wavelengths of 625 nm, 515 nm, and 455 nm.

9. An organic light emitting diode (OLED) device, comprising components arranged in the following order:
a substrate;
a first electrode;
a cavity including an emissive layer;
a second electrode;
a resonance layer; and
an encapsulant layer,
wherein the resonance layer has a thickness such that red, green, and blue reflectances of the OLED device are substantially equal to one another or within a particular deviation of one another.

10. The OLED device of claim 9, wherein the substrate comprises a flexible film.

11. The OLED device of claim 9, wherein the first electrode comprises a reflective electrode.

12. The OLED device of claim 9, wherein the second electrode comprises a transmissive electrode.

13. The OLED device of claim 9, wherein the encapsulant layer comprises an inorganic layer and an organic layer.

14. The OLED device of claim 9, wherein the resonance layer has a thickness and a material such that red, green, and blue reflectances of the OLED device are substantially equal to one another or within a particular deviation of one another.

15. The OLED device of claim 14, wherein the material is selected based upon an index of refraction of the material.

16. The OLED device of claim 9, wherein the thickness of the resonance layer results in a lowest rms deviation of the red, green, and blue reflectances.

17. The OLED device of claim 9, wherein the OLED device has another resonance layer, and the resonance layer and the another resonance layer have thicknesses such that the red, green, and blue reflectances are substantially equal to one another or within a particular deviation of one another.

18. The OLED device of claim 9, wherein the OLED device has another resonance layer, and the resonance layer and the another resonance layer have thicknesses and materials such that the red, green, and blue reflectances are substantially equal to one another or within a particular deviation of one another.

19. The OLED device of claim 18, wherein the materials are selected based upon indices of refraction of the materials.

20. An organic light emitting diode (OLED) stack, comprising components arranged in the following order:
a first electrode;
a cavity including an emissive layer;
a second electrode; and
a resonance layer,
wherein the resonance layer is configured by calculating red, green, and blue reflectance values of the OLED stack and selecting a thickness of the resonance layer such that the red, green, and blue reflectance values are substantially equal to one another or within a particular deviation of one another.

21. A computer-implemented method of making an organic light emitting diode (OLED) device having a resonance layer, comprising steps of:
providing an OLED stack having a substrate, a first electrode, a cavity including an emissive layer, a second electrode, a resonance layer, and an encapsulant layer;
calculating reflectances of red, green, and blue spectrum of the OLED device to generate, respectively, red, green, and blue reflectance values; and
selecting a thickness of the resonance layer such that the red, green, and blue reflectance values are substantially equal to one another or within a particular deviation of one another.
